(19) United States
(12) Patent Application Publication
(10) Pub. No.: US 2014/0076400 A1
(43) Pub. Date: Mar. 20, 2014

(54) SYSTEM FOR MONITORING OPERATING ANGLE OF SOLAR TRACKER IN REAL TIME

(71) Applicant: INSTITUTE OF NUCLEAR ENERGY RESEARCH, ATOMIC ENERGY COUNCIL, EXECUTIVE YUAN, (US)

(72) Inventors: Cheng-Ban Chung, Taipei City (TW); Tsung-Te Lin, Kaohsiung City (TW); Yi-Ru Hsu, Kinmen County (TW); Chii-Neng Ou Yang, Taoyuan County (TW); Yao-Tung Hsu, Taoyuan County (TW)

(73) Assignee: INSTITUTE OF NUCLEAR ENERGY RESEARCH, ATOMIC ENERGY COUNCIL, EXECUTIVE YUAN, Taoyuan County (TW)

(21) Appl. No.: 13/868,630

(22) Filed: Apr. 23, 2013

(30) Foreign Application Priority Data
Sep. 18, 2012 (TW) 101134118

(51) Int. Cl. H01L 31/042

(52) U.S. Cl. CPC H01L 31/0422
USPC 136/259

(57) ABSTRACT

A system monitors an operating angle of a solar tracker in real time. The system includes a solar tracker, an angle measurement device, and a processing device. The solar tracker carries a CPV module and controls a light receiving side of the CPV module to face the sun squarely. The angle measurement device is disposed on the solar tracker to measure an angle of inclination of the light receiving side of the CPV module and generate a measured signal. The processing device receives and records the measured signal. Furthermore, the system performs computation required for efficiency evaluation and performance rating of the CPV module, using the measured operating angle of the solar tracker and ambient parameters.

### CROSS-REFERENCE TO RELATED APPLICATION

This non-provisional application claims priority under 35 U.S.C. §119(a) on Patent Application No(s). 101134118 filed in Taiwan, R.O.C. on Sep. 18, 2012, the entire contents of which are hereby incorporated by reference.

### FIELD OF THE INVENTION

The present invention relates to systems for monitoring an operating angle of a solar tracker in real time, and more particularly, to a system for monitoring an operating angle of a solar tracker in real time and measuring an angle of inclination of the light receiving side of a concentrated photovoltaic (CPV) module carried by the solar tracker to thereby perform computation required for efficiency evaluation and performance rating of the CPV module.

### BACKGROUND OF THE INVENTION

The prior art related to solar power generation discloses tracking the sun with a solar tracker to ensure that a CPV module can face the sun squarely and thereby enhance the energy conversation efficiency of the CPV module. However, the conventional solar tracker is not capable of monitoring the operating angle of a CPV module in real time; as a result, any blunder that happens to the conventional solar tracker is seldom detected instantly to the detriment of the total of power generation hours.

To meet the need of technology development and commercialization, CPV modules have to be subjected to performance rating in order to facilitate product specification design. A CPV module module comprises a converging lens. Parallel rays of sunlight pass through the converging lens to focus on a receiver. Both sunlight intensity and sunlight incidence angle correlate with the efficiency of energy conversion of the CPV module. Unlike the CPV module which admits parallel rays of sunlight, an indoor simulation-oriented light source intended for evaluating the performance of a photovoltaics(PV) module usually admits scattered light rays which have not yet been subjected to any optical treatment, and thus the incident light rays are unlikely to be focused on a receiver. As a result, indoor exposure is different from outdoor exposure in terms of a measurement result.

Furthermore, according to the prior art, module performance rating is carried out to the CPV module by following the steps of: testing the CPV module; measuring its output power P, and its corresponding ambient parameters, such as direct normal irradiation DNI (W/m²), ambient temperature Ta, and wind speed v; evaluating the output power P, direct normal irradiation DNI (W/m²), ambient temperature Ta, and wind speed v by means of statistical analysis, such as linear regression; and performing analysis and verification on ambient parameters and output power of the CPV module under test, so as for the result of analysis and verification to serve as a reference for the output power performance of the CPV module.

In this regard, the module performance rating of the CPV module is verified under sunlight outdoors, wherein module characteristics of the CPV module are measured with an I-V characteristics measurement apparatus. However, in practice, the output power of a CPV module correlates with the sunlight incidence angle, and thus there is always a difference between the estimated output power calculated with the regression equation and the actual output power (calculated in accordance with CPV module I-V by measuring I-V characteristics), even though the output power of the same CPV module is measured according to the same level of direct normal irradiation DNI, regardless of what season during which the aforesaid output power measurement process is carried out. For example, the CPV module power output efficiency measured under direct normal irradiation of 850 W/m² in Spring is different from the CPV module power output efficiency measured under direct normal irradiation of 850 W/m² in Summer. As a result, it is impossible to estimate or verify the CPV module performance accurately.

The aforesaid prior art is characterized in that a solar tracker tracks the sun by means of a predetermined path of a tracking sensor and a controller, but the solar tracker is not equipped with any device for monitoring the operating angle of the solar tracker in real time; as a result, any blunder that happens to the solar trackers is unlikely to be detected and fixed instantly. Furthermore, if the output power of a CPV module is measured under the same direct normal irradiation DNI but in different seasons, the output power calculated with a regression equation will be different from the actual output power to thereby prevent CPV module performance rated output data from serving as a good reference in practical application, applying to estimation of module performance in practice, and satisfying related needs.

### SUMMARY OF THE INVENTION

It is an objective of the present invention to provide a system for monitoring an operating angle of a solar tracker in real time.

Another objective of the present invention is to provide a system for monitoring an operating angle of a solar tracker in real time, test a concentrated photovoltaic (CPV) module in accordance with the measured operating angle of the solar tracker and ambient parameters, and thus apply the system to efficiency evaluation and performance rating of the CPV module.

In order to achieve the above and other objectives, the present invention provides a system for monitoring an operating angle of a solar tracker in real time, the system being for use in monitoring operation of a CPV module and evaluating performance of the CPV module, the system comprising: a solar tracker for carrying the CPV module and controlling the CPV module to enable a light receiving side thereof to keep facing the sun squarely; an angle measurement device disposed on the solar tracker to measure an angle of inclination of the light receiving side facing the sun squarely and thereby generate a measured signal; and a processing device electrically connected to the angle measurement device to receive and record the measured signal.

In an embodiment, the system for monitoring an operating angle of a solar tracker in real time further comprises an ambient data measurement device electrically connected to the processing device receiving measurement data pertaining to ambient temperature, wind speed, and direct normal irradiation which are measured by the ambient data measurement device.

In an embodiment, the system for monitoring an operating angle of a solar tracker in real time further comprises a CPV module characteristics measurement device connected to the CPV module and electrically connected to the processing device receiving measurement data pertaining to the CPV module I-V characteristics measured by the CPV module characteristics measurement device.

In an embodiment, the processing device comprises a storage unit for storing data received by the processing device.

In an embodiment, the processing device comprises a computation unit which makes reference to the measured signal, ambient temperature, wind speed, and direct normal irradiation to thereby calculate a regression equation P=DNI(a₁+a₂·DNI+a₃·Tₐ+a₄·v+a₅·AM), wherein AM is calculated in accordance with the measured signal, P denotes output power of the CPV module, DNI denotes direct normal irradiation (W/m²), Tₐ denotes ambient temperature (° C.), and v denotes wind speed (m/s).

In an embodiment, the solar tracker comprises a platform, a driving mechanism, a light sensor, and a controller. The platform carries the CPV module. The light sensor senses at least one of sunlight intensity and sunlight incidence angle and outputs a sensing signal. The controller controls the driving mechanism according to the sensing signal so as to rotate the platform, such that the light receiving side of the CPV module keeps facing the sun squarely.

In an embodiment, the angle measurement device is a digital level gauge or an angle sensor. The angle measurement device is disposed on the platform.

In an embodiment, the processing device is connected to a display device for displaying the data received by the processing device.

Hence, the system for monitoring an operating angle of a solar tracker in real time of the present invention monitors the operating angles of the solar tracker and a CPV module carried by the solar tracker in real time to thereby evaluate the accuracy and stability of the solar tracker. The present invention is further characterized in that the system for monitoring an operating angle of a solar tracker in real time can calculate air mass AM with respect to the CPV module in operation in accordance with an angle of inclination of the light receiving side of the CPV module when the light receiving side is facing the sun squarely, perform computation, analysis, and evaluation in accordance with ambient parameters, such as ambient temperature Tₐ, wind speed v, direct normal irradiation DNI, air mass AM, and rated output power, and thus enhance the completeness of the reference data pertaining to the CPV module under test as well as the accuracy in performance prediction, such that the system of the present invention can be applied to setting the specifications of the CPV module, performing performance rating thereof, and determining the timing of power generation of the CPV module under related ambient conditions.

### BRIEF DESCRIPTION OF THE DRAWINGS

Objectives, features, and advantages of the present invention are hereunder illustrated with specific embodiments in conjunction with the accompanying drawings, in which:

FIG. 1 is a schematic view of a system for monitoring an operating angle of a solar tracker in real time according to an embodiment of the present invention;

FIG. 2 is a schematic view of a system for monitoring an operating angle of a solar tracker in real time according to another embodiment of the present invention; and

FIG. 3 is a schematic view of a solar tracker according to an embodiment of the present invention.

### DETAILED DESCRIPTION OF THE PREFERRED EMBODIMENTS

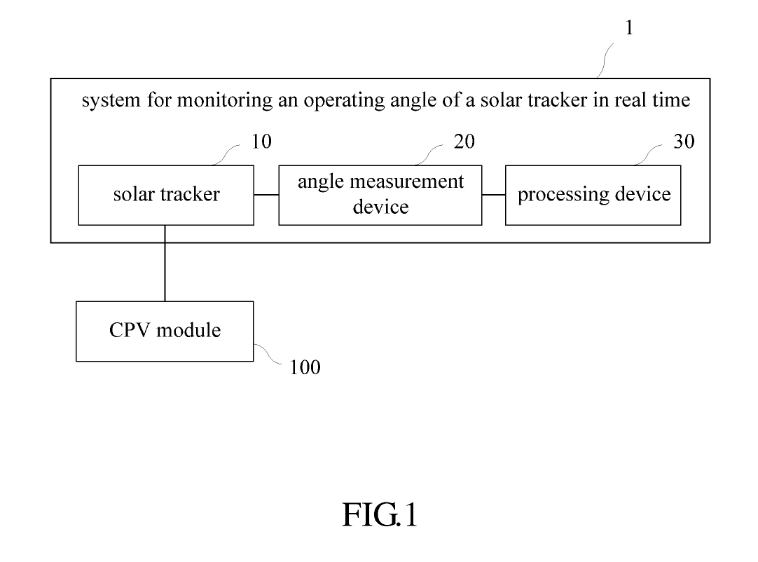

Referring to FIG. 1, there is shown a schematic view of a system 1 for monitoring an operating angle of a solar tracker in real time according to an embodiment of the present invention.

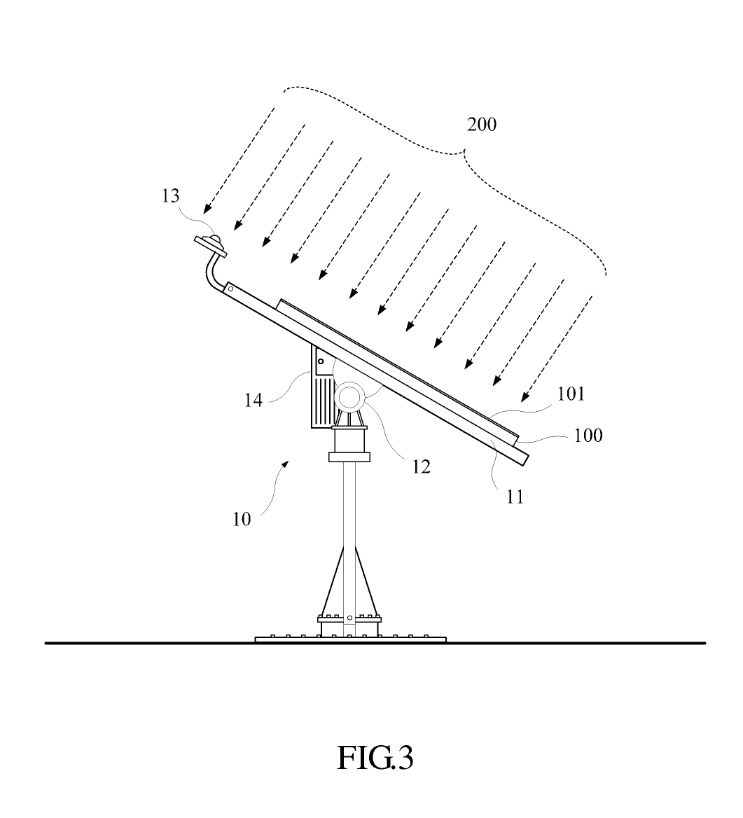

In this embodiment of the present invention, the system 1 for monitoring an operating angle of a solar tracker in real time is for use in performing operation monitoring and efficiency evaluation on a concentrated photovoltaic (CPV) module 100. The system 1 for monitoring an operating angle of a solar tracker in real time essentially comprises a solar tracker 10, an angle measurement device 20, and a processing device 30. The solar tracker 10 carries the CPV module 100 and causes a light receiving side 101 of the CPV module 100 to face the sun squarely (such that the sunlight 200 falls perpendicularly on the light receiving side 101 as shown in FIG. 3.) The angle measurement device 20 is disposed on the solar tracker 10 to measure an angle of inclination of the light receiving side 101 of the CPV module 100 when the light receiving side 101 is facing the sunlight 200 squarely and generate a measured signal. The processing device 30 is electrically connected to the angle measurement device 20 to receive and record the measured signal. In this regard, in this embodiment of the present invention, the system 1 for monitoring an operating angle of a solar tracker in real time monitors the operating angle of the solar tracker 10 in real time to thereby detect and fix any blunder instantly.

Referring to FIG. 3, there is shown a schematic view of a solar tracker according to an embodiment of the present invention. In this embodiment, the solar tracker 10 comprises a platform 11, a driving mechanism 12, a light sensor 13, and a controller 14. The platform 11 carries the CPV module 100. The light sensor 13 senses at least one of the intensity of the sunlight 200 and the incidence angle of the sunlight 200, and then generates a sensing signal. The controller 14 controls the driving mechanism 12 to rotate the platform 11 in accordance with the sensing signal to ensure that the light receiving side 101 of the CPV module 100 keeps facing the sun squarely, that is, to ensure that the sunlight 200 keeps falling perpendicularly on the light receiving side 101 of the CPV module 100. The angle measurement device 20 is a digital level gauge or an angle sensor. The angle measurement device 20 is disposed on the platform 11. In response to real-time variation in the incidence angle of the sunlight 200, the solar tracker 10 sends to the controller 14 a sensing signal generated according to sunlight intensity or sunlight incidence angle sensed by the light sensor 13. The controller 14 controls the driving mechanism 12 to rotate the platform 11 in real time, such that the light receiving side 101 of the CPV module 100 disposed on the platform 11 always faces the sun squarely, allowing the sunlight 200 to fall perpendicularly on the light receiving side 101 of the CPV module 100. The angle measurement device 20 measures an angle of inclination of the light receiving side 101 of the CPV module 100. The angle measurement device 20 measures the included angle between the light receiving side 101 of the CPV module 100 carried by the platform 11 and the horizontal level (or ground level). Alternatively, the angle measurement device 20 measures the angle by which the platform 11 is rotated by the driving mechanism 12 and thereby obtains the included angle between the light receiving side 101 and the horizontal level when the light receiving side 101 is facing the sun squarely (i.e., the angle of inclination of the light receiving side 101 facing the sun squarely) as well as the state of operation of the solar tracker 10 in real time, thereby rendering it easy and efficient to monitor the actual situation and performance of the CPV module 100 in operation.

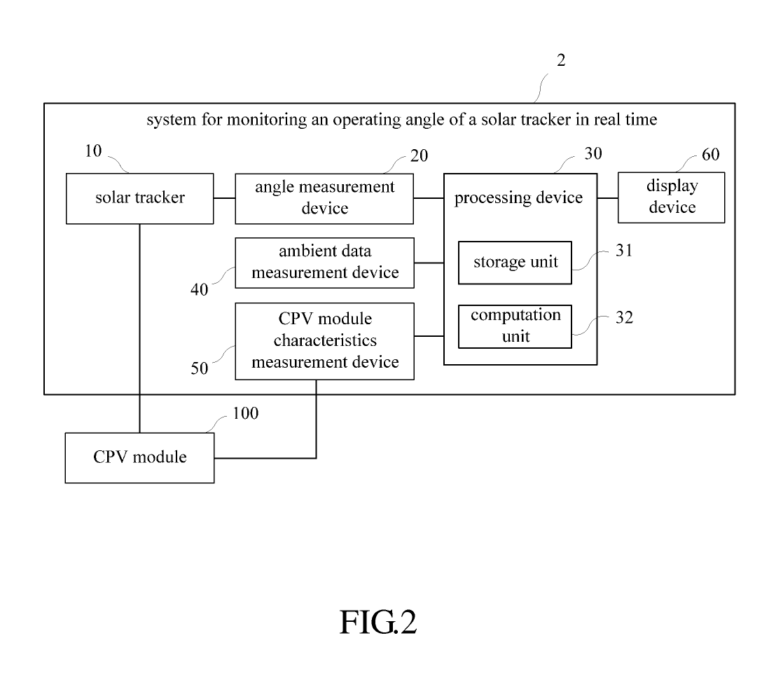

Referring to FIG. 2, there is shown a schematic view of a system 2 for monitoring an operating angle of a solar tracker in real time according to another embodiment of the present invention.

In another embodiment of the present invention, the system 2 for monitoring an operating angle of a solar tracker in real time is for use in evaluating the performance of CPV module 100 and thereby gathering data required for performing efficiency evaluation and output data rating on the CPV module 100.

In this embodiment, the system 2 for monitoring an operating angle of a solar tracker in real time further comprises an ambient data measurement device 40 electrically connected to the processing device 30. The processing device 30 receives measurement data pertaining to ambient temperature Tₐ, wind speed v, and direct normal irradiation DNI which are measured with the ambient data measurement device 40, wherein the ambient temperature Tₐ, wind speed v, and direct normal irradiation DNI are measured in the course of the operation of the CPV module 100 and the solar tracker 10, to record various ambient parameters which determine the output characteristics of the CPV module 100 and thereby facilitate subsequent evaluation and analysis of the performance and output characteristics of the CPV module 100.

In this embodiment, the system 2 for monitoring an operating angle of a solar tracker in real time further comprises a CPV module characteristics measurement device 50 connected to the CPV module 100 and electrically connected to the processing device 30. The processing device 30 receives measurement data about the I-V characteristics attributed to the CPV module 100 and measured by the CPV module characteristics measurement device 50, so as to measure output current (I) and output voltage (V) of the CPV module 100 in operation during a specific period of time to thereby estimate its power generation performance and efficiency and facilitate subsequent evaluation and analysis of output characteristics and performance of the CPV module 100 in terms of its ambient parameters.

In this embodiment, the processing device 30 comprises a storage unit 31 for storing data received by the processing device 30. The storage unit 31 stores measurement data pertaining to the ambient temperature Tₐ, wind speed v, and direct normal irradiation DNI which are measured by the ambient data measurement device 40 and measurement data pertaining to the I-V characteristics attributed to the CPV module 100 and measured by the CPV module characteristics measurement device 50, so as to store data pertaining to the output characteristics of the CPV module 100 and the ambient parameters regarding the CPV module 100 in operation to thereby evaluate, analyze, and verify the output characteristics and performance of the CPV module 100 in terms of its ambient parameters and enhance the completeness and accuracy of the measurement data about the CPV module 100.

In this embodiment of the present invention, the system 2 for monitoring an operating angle of a solar tracker in real time is characterized in that the processing device 30 comprises a computation unit 32 which makes reference to the measured signal (including one pertaining to an angle of inclination of the light receiving side 101 of the CPV module 100 when the light receiving side 101 is facing the sun squarely), ambient temperature Tₐ, wind speed v, and direct normal irradiation DNI to thereby calculate a regression equation P=DNI(a₁+a₂·DNI+a₃·Tₐ+a₄·v+a₅·AM), wherein AM denotes air mass (calculated in accordance with the measured signal), P denotes output power of the CPV module 100, DNI denotes direct normal irradiation (W/m²), Tₐ denotes ambient temperature (° C.), and v denotes wind speed (m/s).

Air mass AM is defined as a level of the attenuate effect of the atmosphere on the amount of sunlight received by the earth surface mainly because of absorption of ultraviolet radiation by ozone layer, absorption of infrared radiation by water vapor, and scattering of sunlight by dust and suspended particles in the atmosphere. Given a sunlight incidence angle θ which is defined as the included angle between a sunlight ray incident on a surface and the line perpendicular to the surface at the point of incidence, AM is expressed as equal to secθ. When AM=0, areas immediately outside the atmosphere is subjected to sunlight radiation of 1353 W/m². When AM=1, sunlight falls perpendicularly on the earth surface as is the case where the sea is exposed to the sun on a sunny summer day, and the earth surface is subjected to sunlight radiation of 925 W/m². Given θ=48.2° and AM=1.5, roads in general are subjected to sunlight radiation of 844 W/m² (or 1000 W/m² as set forth by IEC 904-1 instead) on a sunny day, wherein the “AM=1.5” scenario complies with either of two types of standard, namely AM1.5G (Global) and AM1.5D (Direct), with the AM1.5G standard being applicable to efficiency tests performed on CPV modules in general.

In this embodiment of the present invention, the system 2 for monitoring an operating angle of a solar tracker in real time is characterized in that air mass AM is calculated in accordance with the measured signal. That is to say, air mass AM is calculated in accordance with the sunlight incidence angle θ which, in turn, is calculated in accordance with an angle of inclination of the light receiving side 101 of the CPV module 100 when the light receiving side 101 is facing the sun squarely (see FIG. 3).

In this regard, the computation unit 32 calculates output power P in accordance with the data descriptive of the I-V characteristics of the CPV module 100 and stored in the storage unit 31, calculates air mass AM in accordance with the measured signal, calculates the coefficients a₁, a₂, a₃, a₄, a₅ in the regression equation P=DNI(a₁+a₂·DNI+a₃·Tₐ+a₄·v+a₅·AM) with respect to ambient parameters, including ambient temperature Tₐ, wind speed v, and direct normal irradiation DNI, and thus obtain the module performance analysis equation P=DNI(a₁+a₂·DNI+a₃·Tₐ+a₄·v+a₅·AM) of the CPV module 100. The module performance analysis equation is applicable to evaluation and verification of the performance of the CPV module 100. The sunlight incidence angle θ and ambient parameters (ambient temperature Tₐ, wind speed v, and direct normal irradiation DNI), which can be measured while the CPV module 100 is operating, are substituted into the module performance analysis equation to thereby calculate the output power of the CPV module 100, identify those ambient conditions which are suitable for the operation of the CPV module 100, determine the timing of operation and power generation performed by the CPV module 100, and thus optimize power generation performance. Furthermore, the module performance analysis equation serves as a reference basis for setting the performance rating and specifications of the CPV module 100.

In this embodiment of the present invention, the system 2 for monitoring an operating angle of a solar tracker in real time is characterized in that the processing device 30 can be connected to a display device 60 for displaying data received by the processing device 30. That is to say, the display device 60 displays the measured signal and ambient parameters (ambient temperature Tₐ, wind speed v, and direct normal irradiation DNI, and even displays the result of an analysis process carried out by the computation unit 32.

Hence, in an embodiment of the present invention, the system for monitoring an operating angle of a solar tracker in real time can monitor in real time the operating angles of a solar tracker and a CPV module carried by the solar tracker and evaluate the accuracy and stability of the solar tracker. In another embodiment of the present invention, the system for monitoring an operating angle of a solar tracker in real time can calculate air mass AM with respect to the CPV module in operation in accordance with an angle of inclination of the light receiving side of the CPV module when the light receiving side is facing the sun squarely, perform computation, analysis, and evaluation in accordance with ambient parameters, such as ambient temperature Tₐ, wind speed v, direct normal irradiation DNI, air mass AM, and rated output power, and thus enhance the completeness of the reference data pertaining to the CPV module under test as well as the accuracy in performance prediction, such that the system of the present invention can be applied to setting the specifications of the CPV module, performing performance rating thereof, and determining the timing of power generation of the CPV module under related ambient conditions.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A system for monitoring an operating angle of a solar tracker in real time, the system being for use in monitoring operation of a concentrated photovoltaic (CPV) module and evaluating performance of the CPV module, the system comprising:
a solar tracker for carrying the CPV module and controlling the CPV module to enable a light receiving side thereof to keep facing the sun squarely;
an angle measurement device disposed on the solar tracker to measure an angle of inclination of the light receiving side facing the sun squarely and thereby generate a measured signal; and
a processing device electrically connected to the angle measurement device to receive and record the measured signal.

2. The system of claim 1, further comprising an ambient data measurement device electrically connected to the processing device receiving measurement data pertaining to ambient temperature, wind speed, and direct normal irradiation which are measured by the ambient data measurement device.

3. The system of claim 1, further comprising a CPV module characteristics measurement device connected to the CPV module and electrically connected to the processing device, the processing device receiving measurement data pertaining to I-V characteristics attributed to the CPV module and measured by the CPV module characteristics measurement device.

4. The system of claim 2, further comprising a CPV module characteristics measurement device connected to the CPV module and electrically connected to the processing device, the processing device receiving measurement data pertaining to I-V characteristics attributed to the CPV module and measured by the CPV module characteristics measurement device.

5. The system of claim 3, wherein the processing device comprises a storage unit for storing data received by the processing device.

6. The system of claim 4, wherein the processing device comprises a storage unit for storing data received by the processing device.

7. The system of claim 5, wherein the processing device comprises a computation unit which makes reference to the measured signal, ambient temperature, wind speed, and direct normal irradiation to thereby calculate a regression equation
P=DNI(a₁+a₂·DNI+a₃·Tₐ+a₄·v+a₅·AM),
wherein AM is calculated in accordance with the measured signal, P denotes output power of the CPV module, DNI denotes direct normal irradiation (W/m²), Tₐ denotes ambient temperature (° C.), and v denotes wind speed (m/s).

8. The system of claim 6, wherein the processing device comprises a computation unit which makes reference to the measured signal, ambient temperature, wind speed, and direct normal irradiation to thereby calculate a regression equation
P=DNI(a₁+a₂·DNI+a₃·Tₐ+a₄·v+a₅·AM),
wherein AM is calculated in accordance with the measured signal, P denotes output power of the CPV module, DNI denotes direct normal irradiation (W/m²), Tₐ denotes ambient temperature (° C.), and v denotes wind speed (m/s).

9. The system of claim 1, wherein the solar tracker comprises a platform, a driving mechanism, a light sensor, and a controller, the platform carrying the CPV module, the light sensor sensing at least one of sunlight intensity and sunlight incidence angle and outputting a sensing signal, and the controller controlling the driving mechanism according to the sensing signal so as to rotate the platform, such that the light receiving side of the CPV module keeps facing the sun squarely.

10. The system of claim 9, wherein the angle measurement device is one of a digital level gauge and an angle sensor, and the angle measurement device is disposed on the platform.

11. The system of claim 1, wherein the processing device is connected to a display device to display data received by the processing device.
